(19) United States
(12) Patent Application Publication
(10) Pub. No.: US 2024/0263853 A1
(43) Pub. Date: Aug. 8, 2024

(54) INTEGRATED REFRIGERATION APPARATUS

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/420,950

(22) Filed: Jan. 24, 2024

(30) Foreign Application Priority Data
Feb. 6, 2023 (CN) 202310080989.0

(51) Int. Cl. F25B 41/40; F25B 5/02; F25B 41/20

(52) U.S. Cl. CPC F25B 41/00; F25B 25/00; F25D 16/00; H05K 7/20818; F25B 2400/0401; F25B 2400/0411; H05K 7/20309; H05K 7/20318; H05K 7/20327

(57) ABSTRACT

The present disclosure discloses an integrated refrigeration apparatus, which at least includes a body, a liquid cooling system, and an air cooling system. The liquid cooling system and the air cooling system are installed in the body. The body has an outdoor air inlet, an outdoor air outlet, an operating air inlet, and an operating air outlet. The liquid cooling system at least includes a dry cooler and a liquid supply and return pipe connected in series with the dry cooler, where the dry cooler is positioned between the outdoor air inlet and the outdoor air outlet. The air cooling system at least includes a heat exchange core, where an internal circulation air inlet of the heat exchange core is interconnected to the operating air inlet, and an internal circulation air outlet of the heat exchange core is interconnected to the operating air outlet.

### CROSS REFERENCE TO RELATED APPLICATION

This application claims priority to Chinese patent application Ser. No. 202310080989.0, titled “INTEGRATED REFRIGERATION APPARATUS” and filed to the China National Intellectual Property Administration on Feb. 6, 2023, the entire contents of which are incorporated herein by reference.

### TECHNICAL FIELD

The present disclosure relates to the field of refrigeration devices, and more particularly, to an integrated refrigeration apparatus.

### BACKGROUND

High-performance operation of devices naturally leads to generation of heat. Therefore, how to better refrigerate the devices has become an important topic that needs to be studied in various fields.

For example, in the field of server devices, to better cool the servers, a combination of liquid cooling and air cooling is generally used for heat dissipation.

However, the existing liquid cooling and air cooling are separately provided in corresponding racks, forming two apparatuses, which leads to complexity of the entire refrigeration system and increase of a floor area, making it difficult to arrange in narrow areas.

### SUMMARY

An objective of the present disclosure is to provide an integrated refrigeration apparatus that integrates a liquid cooling system and an air cooling system to facilitate installation and arrangement.

To achieve the above objective, in one aspect the present disclosure provides an integrated refrigeration apparatus, which at least includes a body, a liquid cooling system, and an air cooling system. The liquid cooling system and the air cooling system are installed in the body. The body has an outdoor air inlet, an outdoor air outlet, an operating air inlet, and an operating air outlet. The liquid cooling system at least includes a dry cooler and a liquid supply and return pipe connected in series with the dry cooler, where the dry cooler is positioned between the outdoor air inlet and the outdoor air outlet. The air cooling system at least includes a heat exchange core, where an internal circulation air inlet of the heat exchange core is interconnected to the operating air inlet, and an internal circulation air outlet of the heat exchange core is interconnected to the operating air outlet.

To achieve the above objective, in another aspect the present disclosure also provides an integrated refrigeration apparatus, which at least includes a body, a liquid cooling system and an air cooling system, where the liquid cooling system and the air cooling system are installed in the body. The body has an outdoor air inlet, an outdoor air outlet, an operating air inlet, and an operating air outlet. The liquid cooling system at least includes a dry cooler and a liquid supply and return pipe connected in series with the dry cooler, where the dry cooler is positioned between the outdoor air inlet and the outdoor air outlet. The air cooling system at least includes a condenser, an evaporator, an expansion valve and a compressor, where the condenser is positioned between the outdoor air inlet and the outdoor air outlet, and the evaporator is positioned at the operating air outlet to allow hot air entering via the operating air inlet to exchange heat through the evaporator and to be discharged through the operating air outlet.

As can be seen, according to the technical solutions provided in the present disclosure, the liquid cooling system and the air cooling system are integrated into one body. In this way, the liquid cooling system and the air cooling system can be integrated into one refrigeration module. When needed, the refrigeration module may be directly installed together with a device to be refrigerated to complete the installation and arrangement. Thus, operation is convenient and simple, and installation area can also be reduced, making it suitable for installation in narrow areas. Furthermore, the dry cooler and the heat exchange core are positioned between the outdoor air inlet and the outdoor air outlet. The dry cooler and the heat exchange core share one external air heat exchange channel, which can further simplify the structure of the refrigeration apparatus, and reduce manufacturing costs and manufacturing complexity.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic front view of an integrated refrigeration apparatus according to an embodiment of the present disclosure;

FIG. 2 is a schematic vertical view of the integrated refrigeration apparatus according to an embodiment of the present disclosure; and

FIG. 3 is a schematic workflow diagram of a refrigeration cycle according to an embodiment of the present disclosure.

### DETAILED DESCRIPTION

Detailed description of embodiments of the present disclosure will further be made below with reference to drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

High-performance operation of devices naturally leads to generation of heat. Therefore, how to better refrigerate the devices has become an important topic that needs to be studied in various fields.

For example, in the field of server devices, as heat dissipation of GPU/CPU continues to increase, power consumption for refrigeration of data centers increases, and power usage effectiveness (PUE) of the data centers continues to increase. In this case, a liquid cold plate refrigeration solution is widely used as a mainstream solution in the data center industry. However, in the liquid cold plate refrigeration solution, only part of cold energy can be taken away, while remaining part of the cold energy needs to be taken away by a separate cold source. Therefore, two sets of cold source systems need to be designed. That is, to better cool the servers, in the existing technologies, a combination of liquid cooling and air cooling is generally used for heat dissipation.

However, the existing liquid cooling and air cooling are separately provided in corresponding racks, forming two apparatuses, which leads to complexity of the entire refrigeration system and increase of a floor area, making it difficult to arrange in narrow areas.

Therefore, how to improve the existing refrigeration system to simplify the refrigeration system, reduce installation area and facilitate installation arrangement has become a problem urgently to be solved.

The technical solutions in the embodiments of the present disclosure will be clearly and completely described below with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

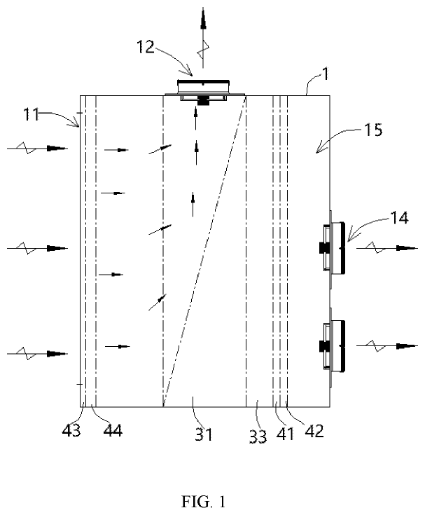

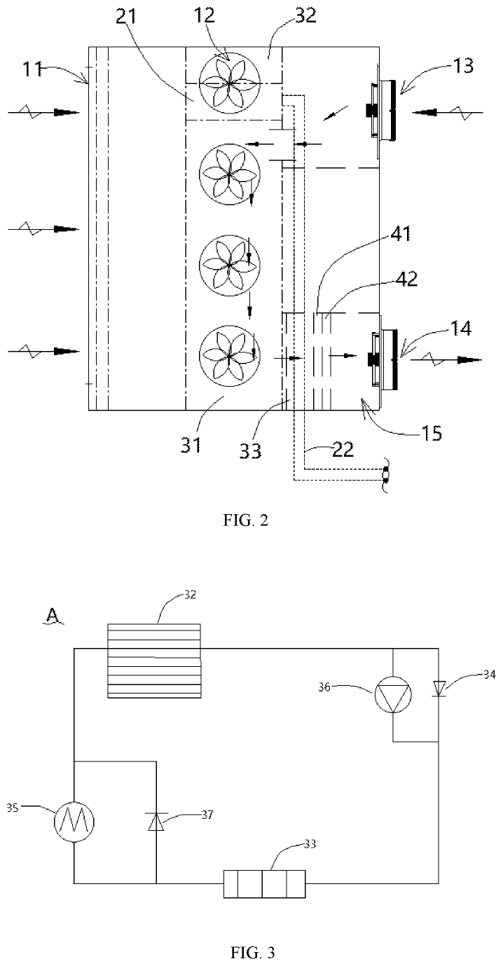

Referring to FIG. 1 and FIG. 2 together, in an implementable embodiment, the integrated refrigeration apparatus may at least include a body 1, a liquid cooling system, and an air cooling system. The liquid cooling system and the air cooling system are installed in the body 1, such that the liquid cooling system and the air cooling system are integrated into one refrigeration module. When needed, the refrigeration module may be directly installed together with a device to be refrigerated to complete the installation and arrangement. Thus, operation is convenient and simple, and installation area can also be reduced compared to the existing separate installation manner, making it suitable for installation in narrow areas.

In this embodiment, the body 1 has an outdoor air inlet 11, an outdoor air outlet 12, an operating air inlet 13, and an operating air outlet 14. The outdoor air inlet 11 allows external air to enter, and the external air is discharged through the outdoor air outlet 12. The operating air inlet 13 and the operating air outlet 14 are interconnected to space inside the device to be refrigerated, such that hot air generated by the device to be refrigerated flows through the operating air inlet 13 into the body 1. After heat exchange, the hot air becomes cold air, which is discharged through the operating air outlet 14. The liquid cooling system may at least include a dry cooler 21 and a liquid supply and return pipe 22 connected in series with the dry cooler 21. It is to be pointed out that the liquid supply and return pipe 22 refers to a liquid supply pipe and a liquid return pipe. The liquid supply pipe is interconnected to a liquid outlet of the dry cooler 21, the liquid return pipe is interconnected to a liquid inlet of the dry cooler 21, and other end of the liquid supply pipe and other end of the liquid return pipe are interconnected to the liquid cold plate. The liquid supply pipe and the liquid return pipe should also be connected in series with a pump body to drive a refrigerating medium to circulate in the liquid cooling system. The dry cooler 21 is positioned between the outdoor air inlet 11 and the outdoor air outlet 12, such that the external air entering from the outdoor air inlet 11 and discharged through the outdoor air outlet 12 may exchange heat with the dry cooler 21. The air cooling system at least includes a heat exchange core 31, where an internal circulation air inlet of the heat exchange core 31 is interconnected to the operating air inlet 13, and an internal circulation air outlet of the heat exchange core 31 is interconnected to the operating air outlet 14. That is, the external air entering from the operating air inlet 13 and discharged through the operating air outlet 14 may flow through the heat exchange core 31, thereby exchanging heat with internal circulation air entering from the operating air inlet 13 and discharged through the operating air outlet 14, to achieve heat exchange with the internal circulation air.

In practical applications, the operating air inlet 13 and the operating air outlet 14 are respectively interconnected to the space where the device to be refrigerated is positioned. The liquid cold plate interconnected to the liquid supply and return pipe 22 may be attached to a heat source of the device to be refrigerated. The external air entering from the operating air inlet 13 and discharged through the operating air outlet 14 may simultaneously exchange heat with the heat exchange core 31 and the dry cooler 21. In this way, the liquid cooling system and the air cooling system may simultaneously refrigerate the space where the device to be refrigerated is positioned and the heat source. Moreover, the dry cooler 21 and the heat exchange core 31 may share one external air heat exchange channel, which can further simplify the structure of the refrigeration apparatus, and can reduce manufacturing costs and manufacturing complexity.

It is to be pointed out that reference may be made to the existing technologies for specific structures of the dry cooler 21 and the heat exchange core 31, which are not to be described in detail here.

In an implementable embodiment, as shown in FIG. 2 and FIG. 3, air outlet channel 15 is connected between the internal circulation air outlet and the operating air outlet 14. The air cooling system also includes a condenser 32, an evaporator 33, an expansion valve 34, and a compressor 35. The condenser 32, the evaporator 33, the expansion valve 34 and the compressor 35 are connected in series with each other to form a refrigeration cycle A. The condenser 32 is positioned between the outdoor air inlet 11 and the outdoor air outlet 12, and the evaporator 33 is installed in the air outlet channel 15.

In this embodiment, the internal circulation air not only can exchange heat with the external air through the heat exchange core, but also can carry out secondary heat exchange through the evaporator in refrigeration cycle A to meet different heat dissipation needs.

The above air cooling system may also include a fluorine pump 36 and a one-way valve 37. The fluorine pump 36 is connected in series in the refrigeration cycle A, and the fluorine pump 36 is connected in parallel with the expansion valve 34. The one-way valve 37 is connected in series in the refrigeration cycle A, and the one-way valve 37 is connected in parallel with the compressor 35. In this way, the fluorine pump 36 or the compressor 35 may be selectively started according to actual usage requirements, thereby further expanding applicable usage environment and reducing energy consumption.

Further, the heat exchange core 31, the dry cooler 21, and the condenser 32 should be arranged side by side. In this way, when entering the body 1 through the outdoor air inlet, the external air may evenly blow through the heat exchange core 31, the dry cooler 21 and the condenser 32, thereby exchanging heat and preventing the heat exchange core 31, the dry cooler 21 and the condenser 32 from mutually overlapping, and thus avoiding adversely affecting heat exchange effects.

In an implementable embodiment, a humidification and dehumidification section 41 is installed in the air outlet channel 15, and the humidification and dehumidification section 41 is positioned between the operating air outlet 14 and the evaporator 33. In this way, after temperature and humidity requirements are met, the internal circulation air is delivered into the space where the device to be refrigerated is positioned.

It is to be pointed out that the humidification and dehumidification section 41 is one of functional sections of a combined air handling unit. Due to seasonal changes, when air humidity is required to be reduced or increased, air dehumidification or humidification treatment is carried out. Reference may be made to the existing technologies for the specific structure of the humidification and dehumidification section 41, which is not to be described in detail here.

Further, a filter section 42 may also be installed in the air outlet channel 15 to filter airflow flowing through the air outlet channel 15, thereby ensuring cleanliness of the internal circulation air entering the space where the device to be refrigerated is positioned.

In practical applications, the filter section 42 may be an initial, medium or sub-high efficiency filter section or a chemical filter section.

Further, a rainproof shutter 43 and a filter mesh 44 are installed at the outdoor air inlet 11 to prevent rainwater and debris from entering from the outdoor air inlet 11.

In one embodiment, the operating air inlet 13 and the operating air outlet 14 are positioned on the same side of the body 1, thereby facilitating interconnection with the space where the device to be refrigerated is positioned. The outdoor air inlet 11, the outdoor air outlet 12, and the operating air inlet 13 are respectively positioned on different side faces of the body 1. In one aspect, this facilitates device installation and operation, and in another aspect, this can prevent the external air from mixing with each other, thus avoiding adversely affecting heat dissipation effects of the dry cooler 21, of the heat exchange core 31, and of the condenser 32.

Based on the same inventive concept, the present disclosure also provides an integrated refrigeration apparatus, which may at least include a body 1, a liquid cooling system and an air cooling system, where the liquid cooling system and the air cooling system are installed in the body 1. The body 1 has an outdoor air inlet 11, an outdoor air outlet 12, an operating air inlet 13, and an operating air outlet 14. The liquid cooling system at least includes a dry cooler 21 and a liquid supply and return pipe 22 connected in series with the dry cooler 21, where the dry cooler 21 is positioned between the outdoor air inlet 11 and the outdoor air outlet 12. The air cooling system at least includes a condenser 32, an evaporator 33, an expansion valve 34, and a compressor 35. The condenser 32 is positioned between the outdoor air inlet 11 and the outdoor air outlet 12, and the evaporator 33 is positioned at the operating air outlet 14 to allow hot air entering via the operating air inlet 13 to exchange heat through the evaporator 33 and to be discharged through the operating air outlet 14.

It is to be pointed out that, unlike the integrated refrigeration apparatus mentioned above, the air cooling system of the present disclosure may use the refrigeration cycle A separately instead of using the heat exchange core. Reference may be made to the contents of the above embodiments for specific structures of the liquid cooling system, the air cooling system and the body, and for connection relationships between the liquid cooling system and the air cooling system and the body, which are not to be described in detail here.

Further, the air cooling system also includes a fluorine pump 36 and a one-way valve 37. The fluorine pump 36 is connected in series in the refrigeration cycle A, and the fluorine pump 36 is connected in parallel with the expansion valve 34. The one-way valve 37 is connected in series in the refrigeration cycle A, and the one-way valve 37 is connected in parallel with the compressor 35.

As can be seen, according to the technical solutions provided in the present disclosure, the liquid cooling system and the air cooling system are integrated into one body. In this way, the liquid cooling system and the air cooling system can be integrated into one refrigeration module. When needed, the refrigeration module may be directly installed together with a device to be refrigerated to complete the installation and arrangement. Thus, operation is convenient and simple, and installation area can also be reduced, making it suitable for installation in narrow areas. Furthermore, the dry cooler and the heat exchange core are positioned between the outdoor air inlet and the outdoor air outlet. The dry cooler and the heat exchange core share one external air heat exchange circulation, which can further simplify the structure of the refrigeration apparatus, and reduce manufacturing costs and manufacturing complexity.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. An integrated refrigeration apparatus, at least comprising a body, a liquid cooling system and an air cooling system, wherein the liquid cooling system and the air cooling system are installed in the body;
the body has an outdoor air inlet, an outdoor air outlet, an operating air inlet, and an operating air outlet;
the liquid cooling system at least comprises a dry cooler and a liquid supply and return pipe connected in series with the dry cooler, wherein the dry cooler is positioned between the outdoor air inlet and the outdoor air outlet; and
the air cooling system at least comprises a heat exchange core, wherein an internal circulation air inlet of the heat exchange core is interconnected to the operating air inlet, and an internal circulation air outlet of the heat exchange core is interconnected to the operating air outlet.

2. The integrated refrigeration apparatus according to claim 1, wherein an air outlet channel is connected between the internal circulation air outlet and the operating air outlet;
the air cooling system further comprises a condenser, an evaporator, an expansion valve and a compressor, wherein the condenser, the evaporator, the expansion valve and the compressor are connected in series with each other to form a refrigeration cycle; and
the condenser is positioned between the outdoor air inlet and the outdoor air outlet, and the evaporator is installed in the air outlet channel.

3. The integrated refrigeration apparatus according to claim 2, wherein the heat exchange core, the dry cooler and the condenser are arranged side by side.

4. The integrated refrigeration apparatus according to claim 3, wherein the air cooling system further comprises a fluorine pump and a one-way valve;
the fluorine pump is connected in series in the refrigeration cycle, and the fluorine pump is connected in parallel with the expansion valve; and
the one-way valve is connected in series in the refrigeration cycle, and the one-way valve is connected in parallel with the compressor.

5. The integrated refrigeration apparatus according to claim 4, wherein a humidification and dehumidification section is installed in the air outlet channel, and the humidification and dehumidification section is positioned between the operating air outlet and the evaporator.

6. The integrated refrigeration apparatus according to claim 5, wherein a filter section is installed in the air outlet channel to filter an airflow flowing through the air outlet channel.

7. The integrated refrigeration apparatus according to claim 5, wherein a rainproof shutter and a filter mesh are installed at the outdoor air inlet.

8. The integrated refrigeration apparatus according to claim 1, wherein the operating air inlet and the operating air outlet are positioned on a same side of the body; and
the outdoor air inlet, the outdoor air outlet and the operating air inlet are respectively positioned on different side faces of the body.

9. An integrated refrigeration apparatus, at least comprising a body, a liquid cooling system and an air cooling system, wherein the liquid cooling system and the air cooling system are installed in the body;
the body has an outdoor air inlet, an outdoor air outlet, an operating air inlet, and an operating air outlet;
the liquid cooling system at least comprises a dry cooler and a liquid supply and return pipe connected in series with the dry cooler, wherein the dry cooler is positioned between the outdoor air inlet and the outdoor air outlet; and
the air cooling system at least comprises a condenser, an evaporator, an expansion valve and a compressor, wherein the condenser is positioned between the outdoor air inlet and the outdoor air outlet, and the evaporator is positioned at the operating air outlet to allow hot air entering via the operating air inlet to exchange heat through the evaporator and to be discharged through the operating air outlet.

10. The integrated refrigeration apparatus according to claim 9, wherein the air cooling system further comprises a fluorine pump and a one-way valve;
the fluorine pump is connected in series in the refrigeration cycle, and the fluorine pump is connected in parallel with the expansion valve; and
the one-way valve is connected in series in the refrigeration cycle, and the one-way valve is connected in parallel with the compressor.
